(19) United States
(12) Patent Application Publication
(10) Pub. No.: US 2007/0235328 A1
(43) Pub. Date: Oct. 11, 2007

(54) POWER SUPPLY DEVICE

(75) Inventors: Goetz TESCHNER, Dresden (DE); Goetz GROSSER, Dresden (DE); Wolfgang FRIEDEMANN, Dresden (DE); Dietmar SCHULZE, Dresden (DE)

Correspondence Address: HESLIN ROTHENBERG FARLEY & MESITI PC, 5 COLUMBIA CIRCLE, ALBANY, NY, 12203, US

(73) Assignee: VON ARDENNE ANLAGENTECHNIK GMBH, Dresden (DE)

(21) Appl. No.: 11/689,529

(22) Filed: Mar. 22, 2007

(30) Foreign Application Priority Data
Mar. 23, 2006 (DE) 20 2006 004 791.3

(51) Int. Cl. C23C 14/00

(52) U.S. Cl. 204/298.16

(57) ABSTRACT

A high power supply device for a vacuum coating system with at least one magnetron disposed in a coating chamber comprises a line adapter for a DC power supply for converting a line voltage into a DC voltage, a line connection for supplying the line voltage, and a medium-frequency generator supplied by the DC power supply for providing a medium-frequency voltage with at least one load connection for supplying the magnetron with the medium-frequency voltage. The line adapter for the DC power supply in the medium-frequency generator are disposed in a common housing. Dimensions in the housing are adapted to dimensions of the coating chamber and the high frequency supply device is adapted to be mechanically and electrically connected to a magnetron by a connection which is direct and can be undone.

### BACKGROUND ART

The invention relates to a power supply device for a vacuum coating system provided with at least one magnetron, in particular for inline vacuum coating systems according to the preamble of claim 1.

Vacuum coating systems are used for coating various, even larger, components, where in said vacuum coating systems one or more vacuum chambers, separated from one another by vacuum valves, are disposed in a line. Therein, at least one of the vacuum chambers is formed as a coating chamber and for this purpose is equipped with at least one magnetron. For the operation of the magnetron a high power supply unit in connection with a high-power, medium-frequency generator (10 to 100 kHz) in the power range between 10 und 200 kW is required.

The high-power, medium-frequency generator is connected to a line adapter for the DC power supply, said line adapter supplying the required adjustable or regulable DC voltage and comprising an oscillator part supplied by this DC voltage. This oscillator part supplies the medium-frequency voltage needed for the operation of the magnetron.

The oscillator part is usually located, together with the line adapter for the DC power supply, in an electrical cabinet, or at least in a separately disposed housing. The electrical connection of the oscillator to the line adapter for the DC power supply on one side and to the magnetron within the vacuum coating system on the other side is done by cable connections. These cable connections are usually connected to the corresponding components via cable contact points which are fixed by clamping. The length of the cable connections is limited due to the effect on the impedance, the power loss, the interfering radiation, etc. and lies as a rule between 10 and 25 m.

Particularly disadvantageous in this case are the cable connections between the oscillator part and the magnetron, which, in particular at high powers, require a large cross section and are thus mechanically extremely inflexible. Moreover, the clamping and unclamping of the cables required in routine maintenance work is associated with a significant effort.

Furthermore, the inflexibility of the cables makes the universal use of the oscillators for different positions of the magnetron within the vacuum chamber more difficult. That is disadvantageous, in particular in large inline coating systems, since in that case the cable connections frequently have to be laid at coating positions several meters distant from one another.

The limited cable length between the oscillator part and the magnetron also restricts the universal use of the oscillators for all the coating positions in a large inline coating system since in that case there can be 50 or more meters between the first and the last coating position.

In DE 298 19 336 U1 an oscillator arrangement for high-power, medium-frequency generators has been proposed, in which these disadvantages are avoided.

For this, the housing dimensions of the oscillator are adapted to the external geometry of the coating chamber and the oscillator is mechanically and electrically connected to a magnetron, in such a manner that said connection is direct and can be undone. The line adapter for the DC power supply, said line adapter supplying the required adjustable or regulable DC voltage, remains in this realization in an electrical cabinet disposed so as to be spatially separated from the oscillator.

In this way the oscillator can be housed as a separate component directly on the coating chamber so that the cables previously necessary for transmitting the medium-frequency voltage from the oscillator to the magnetron are omitted and no interfering radiation occurs, which previously has been caused by cables carrying medium frequencies.

It has proven to be the case that this concept cannot be applied at powers above 100 kW for reasons of circuit technology.

### BRIEF DESCRIPTION OF THE INVENTION

The objective of the present invention thus consists in specifying a power supply device for vacuum coating systems provided with at least one magnetron, where said power supply device is also usable for power requirements above 100 kW.

The high power supply unit according to the invention for a vacuum coating system with at least one magnetron disposed in a coating chamber comprises a line adapter for the DC power supply, said line adapter serving to convert a line voltage into a DC voltage and comprising a line connection for supplying the line voltage, and comprises a medium-frequency generator supplied by the DC voltage for providing a medium-frequency voltage and comprising at least one load connection for supplying the magnetron with the medium-frequency voltage, where the line adapter for the DC power supply and the medium-frequency generator are disposed in a common housing and is characterized by the fact that the dimensions of the housing are adapted to the dimensions of the coating chamber and the high power supply device can be mechanically and electrically connected to a magnetron, in such a manner that said connection is direct and can be undone.

The power supply device according to the invention makes it possible to dispose the line adapter for the DC power supply and the medium-frequency generator in close spatial proximity to one another and to the magnetron of the vacuum coating system so that the arrangement can also be used for a power requirement of more than 100 kW.

Advantageously, the width of the housing is less than or equal to the length of the coating chamber.

Thereby it is achieved that, even with several coating chambers disposed with one directly behind another, the respective power supply device can be disposed in the vicinity of the magnetron without space problems arising.

In a development of the invention the line connection and each load connection each comprise a plug-in connector for connection to an electrical network or a magnetron in such a manner that said connection can be undone.

Through the capability of using connections which can be plugged in, the removal of the power supply device for the purposes of cleaning and maintaining the vacuum coating system is significantly simplified.

In an advantageous extension of the invention each load connection comprises means for automatically contacting a counterpart provided for this.

For this purpose, for example, guide grooves or bevels can be provided on the plug-in connectors so that the load connection and its counterpart quickly and securely make contact with one another even when they are laterally slightly offset from one another.

A load connection disposed on the underside of the housing is also advantageous.

This development makes it possible to place the power supply device directly on a magnetron suspended from the upper side of the coating chamber so that the load connection is contacted with a corresponding counterpart on the magnetron.

A load connection disposed on the rear side of the housing is also advantageous.

This development makes it possible to place the power supply device next to the coating chamber and to contact a magnetron which is fastened to the side wall of the coating chamber.

According to another development of the invention the housing comprises mechanical guide elements for positioning on the coating chamber, where said mechanical guide elements match corresponding guide elements of the coating chamber.

Thereby, the positioning of the power supply device with respect to the coating chamber is significantly simplified.

Advantageously, the guide elements on the housing are formed as guide pins and the guide elements on the coating chamber are formed as holes of corresponding size.

The forming of the guide elements as guide pins and corresponding holes can be can be carried out in a particularly simple and economical manner. Obviously, holes on the housing of the power supply device and guide pins on the coating chamber can also be provided without abandoning the fundamental concept of the invention.

Particularly advantageously, the guide pins comprise centering cones at their ends.

Thereby, the positioning of the power supply device with respect to the coating chamber is simplified further.

In an extension the guide pins are formed at the same time as positioning feet.

This development has the advantage that the power supply device can be set down on a smooth surface without difficulties and without having to be supported if the power supply device is removed for the purpose of maintenance of the coating chamber.

In a preferred development of the invention the housing is implemented so that it can be carried.

Thereby, maintenance work on the power supply device itself is significantly simplified without the power supply device having to be removed from the coating chamber.

In an equally preferred development of the invention the housing comprises attachment means for transport in a vehicle.

Thereby, the transport of the power supply device is significantly simplified.

### BRIEF DESCRIPTION OF THE DRAWING FIGURES

In the following the invention will be explained in more detail with the aid of embodiment examples and corresponding drawings. Shown therein are:

FIG. 1 a first embodiment example,

FIG. 2 a second embodiment example,

FIG. 3 a third embodiment example.

### DETAILED DESCRIPTION

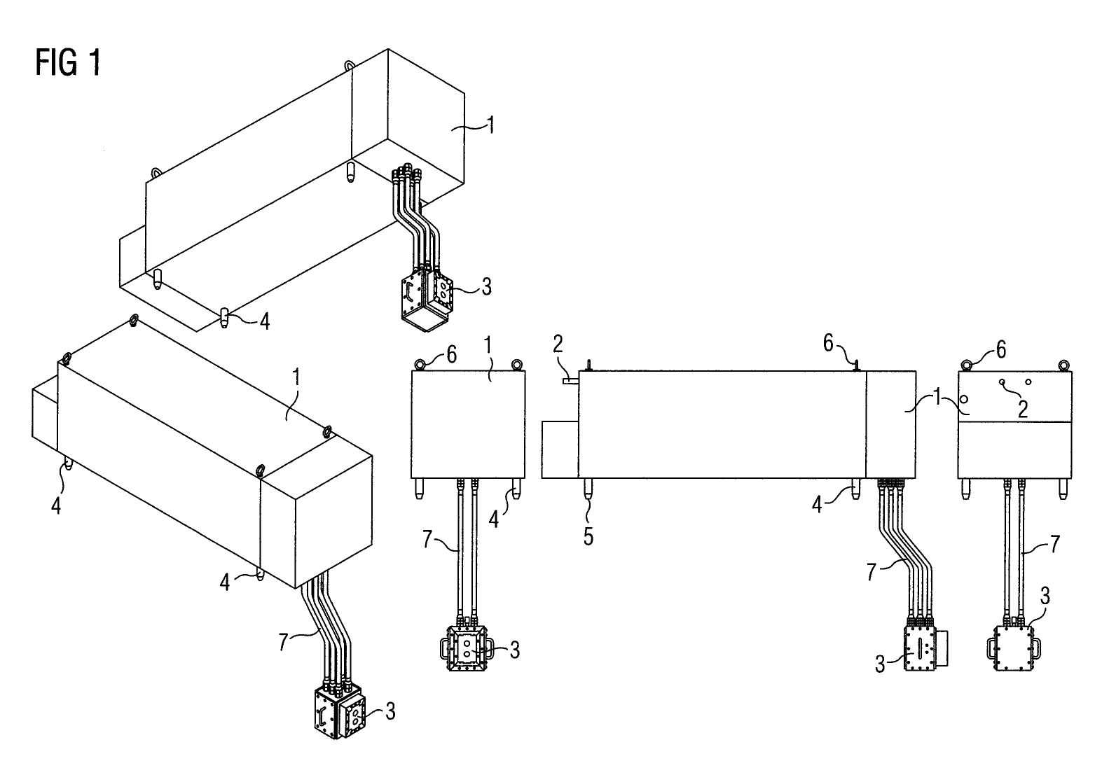

The embodiment example in FIG. 1 is provided for horizontal positioning, for example, along a coating chamber on which a magnetron is disposed in the horizontal direction.

The high power supply device comprises an unrepresented line adapter for the DC power supply, said line adapter serving to convert a line voltage into a DC voltage and comprising a line connection 2 for supplying a line voltage, and comprises an unrepresented medium-frequency generator, supplied by the DC voltage, for providing a medium-frequency voltage and comprising at least one load connection 3 for supplying the magnetron with the medium-frequency voltage.

The line adapter for the DC power supply and the medium-frequency generator are disposed in a common housing 1. The dimensions of the housing 1 are adapted to the dimensions of the coating chambers of a vacuum coating system and the high power supply device can be mechanically and electrically connected to a magnetron, in such a manner that said connection is direct and can be undone.

The width of the housing 1 is chosen so that it is less than or equal to the length of the coating chamber.

The line connection 2 and the load connection 3 each comprise a plug-in connector for connection to an electrical network or a magnetron in such a manner that said connection can be undone. The plug-in connector of the line connection 2 is not represented in the figure.

The load connection 3 comprises means for automatic contacting of a counterpart provided for this, namely guide bevels not represented.

The load connection 3 is disposed by means of flexible connecting lines 7 on the housing 1 so that the magnetron disposed on the side wall of the coating chamber can be contacted.

The housing 1 comprises mechanical guide elements 4 for positioning on the coating chamber, where said mechanical guide elements match corresponding guide elements of the coating chamber and where, in the embodiment example, said mechanical guide elements are formed as guide pins which can engage in holes of corresponding size on the coating chamber. The guide pins 4 comprise at their ends centering cones 5. At the same time, the guide pins 4 are formed as positioning feet.

The housing 1 is implemented so that it can be carried and comprises attachment means 6 for transport in a vehicle, said attachment means being implemented in the embodiment example as ring screws according to DIN 580.

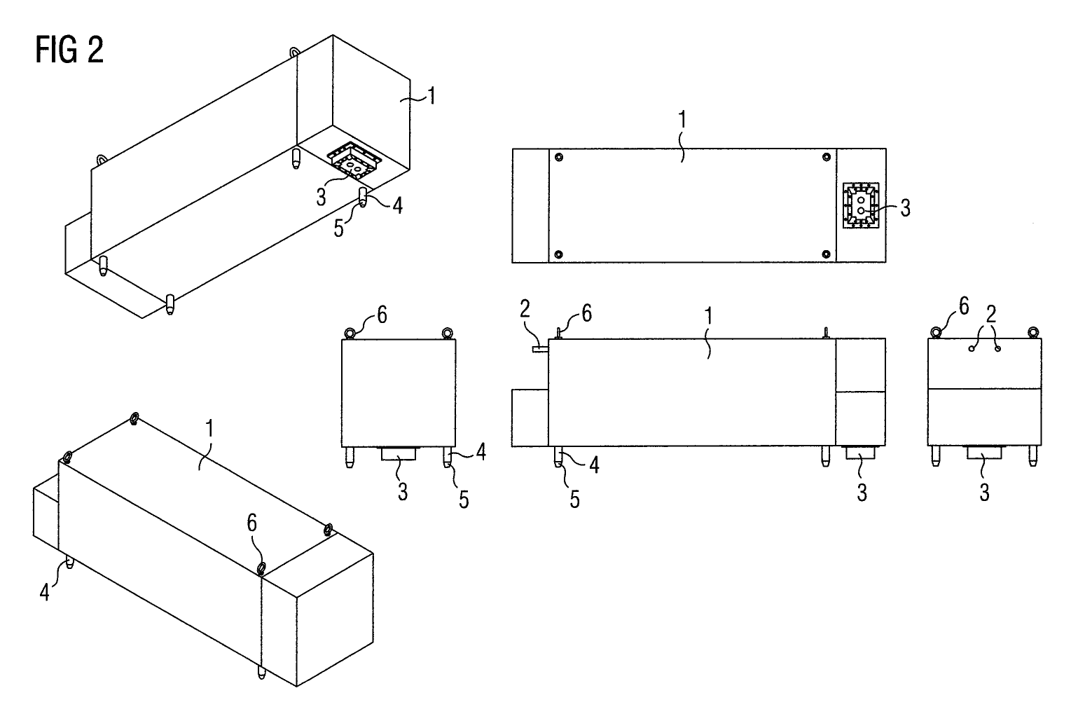

The embodiment example in FIG. 2 is provided for horizontal mounting on a coating chamber in which a magnetron is disposed which is connected to the cover of the coating chamber.

Unlike the embodiment example in FIG. 1, in this embodiment example the load connection 3 is disposed on the underside of the housing 1 so that the magnetron is contacted directly when the high power supply device is mounted on the coating chamber.

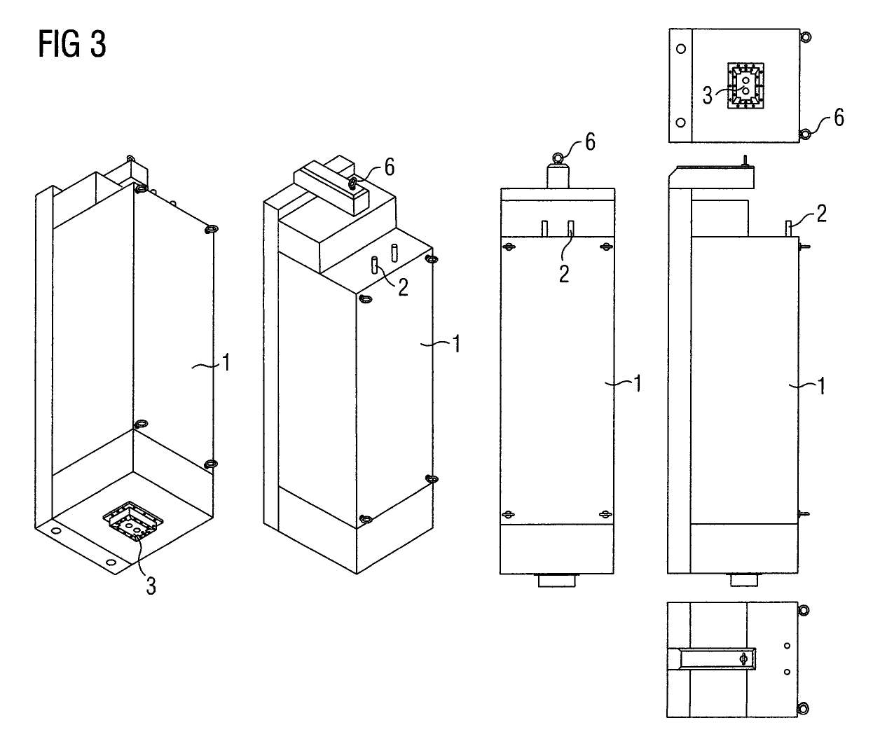

The embodiment example in FIG. 3 is provided for vertical mounting on a coating chamber in which a magnetron is disposed which is connected to the cover of the coating chamber.

Unlike the embodiment examples in FIGS. 1 and 2, in this embodiment example the load connection 3 is disposed on the underside of the housing 1, where the underside of the housing 1 is a narrow side so that the housing 1 is set vertically on the coating chamber. This embodiment example is suitable in particular for use with coating chambers which comprise magnetrons disposed vertically.

The attachment means 6 for transport in vehicle is in turn implemented as a ring screw, where it is disposed in this case so that the housing can be transported in a vertical position, i.e., standing upright.

1. High power supply device for a vacuum coating system with at least one magnetron disposed in a coating chamber, comprising a line adapter for a DC power supply for converting a line voltage into a DC voltage and comprising a line connection for supplying the line voltage and a medium-frequency generator supplied by the DC power supply for providing a medium-frequency voltage with at least one load connection for supplying the at least one magnetron with the medium-frequency voltage, wherein the line adapter for the DC power supply and the medium-frequency generator are disposed in a common housing, dimensions of the housing are adapted to dimensions of the coating chamber and the high power supply device is adapted to be mechanically and electrically connected to a magnetron by a connection which is direct and can be undone.

2. High power supply device according to claim 1, wherein width of the housing is less than or equal to length of the coating chamber.

3. High power supply device according to claim 1, wherein the line connection and each load connection each comprise a plug-in connector for connection to an electrical network or a magnetron in such a manner that said connection can be undone.

4. High power supply device according to claim 1, wherein each load connection comprises means for automatically contacting a counterpart.

5. High power supply device according to claim 1, wherein a load connection of the at least one load connection is disposed on an underside of the housing.

6. High power supply device according to claim 1, wherein a load connection of the at least one load connection is disposed on a rear side of the housing.

7. High power supply device according to claim 1, wherein the housing further comprises mechanical guide elements for positioning on the coating chamber, and said guide elements match corresponding guide elements of the coating chamber.

8. High power supply device according to claim 7, wherein the guide elements on the housing comprise guide pins and the guide elements on the coating chamber comprise holes of corresponding size.

9. High power supply device according to claim 8, wherein the guide pins comprise centering cones at ends of the guide pins.

10. High power supply device according to claim 8, wherein the guide pins serve at the same time as positioning feet.

11. High power supply device according to claim 1, wherein the housing is adapted to be carried.

12. High power supply device according to claim 1, wherein the housing comprises attachment means for transport in a vehicle.
